(19) United States
(12) Patent Application Publication
(10) Pub. No.: US 2021/0005843 A1
(43) Pub. Date: Jan. 7, 2021

(54) ORGANIC ELECTROLUMINESCENT DISPLAY DEVICE AND METHOD FOR PRODUCING SAME

(71) Applicant: SAKAI DISPLAY PRODUCTS CORPORATION, Sakai-shi, Osaka (JP)

(72) Inventor: KATSUHIKO KISHIMOTO, Sakai-shi, Osaka (JP)

(21) Appl. No.: 16/982,527

(22) PCT Filed: Mar. 28, 2018
(86) PCT No.: PCT/JP2018/012953

§ 371 Date: Sep. 18, 2020

(51) Int. Cl. H01L 51/52; H01L 27/32; H01L 51/56

(52) U.S. Cl. CPC H01L 51/5253; H01L 51/56; H01L 27/3246

(57) ABSTRACT

An organic EL display device (100) is provided with an element substrate (20) that has a substrate (1) and a plurality of organic EL elements (3) supported on the substrate, and a thin film encapsulation structure (10) that covers the plurality of organic EL elements. The thin film encapsulation structure is provided with a first inorganic barrier layer (12), an organic barrier layer (14) formed upon the first inorganic barrier layer, and a second inorganic barrier layer (16) formed upon the organic barrier layer. The surface (12S) of the first inorganic barrier layer that is in contact with the organic barrier layer has a plurality of fine protrusions, and the maximum height Rz of the surface roughness profile is 20 nm to less than 100 nm.

### TECHNICAL FIELD

The present invention relates to an organic EL display device and a method for producing the same.

### BACKGROUND ART

Organic EL (Electroluminescent) display devices start being put into practical use. One feature of an organic EL display device is flexibility thereof. Such an organic EL display device includes, in each of pixels, at least one organic EL element (Organic Light Emitting Diode: OLED) and at least one TFT (Thin Film Transistor) controlling an electric current to be supplied to the at least one OLED. Hereinafter, an organic EL display device will be referred to as an “OLED display device”. Such an OLED display device including a switching element such as a TFT or the like for each of OLEDs is called an “active matrix OLED display device”. A substrate including the TFTs and the OLEDs will be referred to as an “element substrate”.

An OLED (especially, an organic light emitting layer and a cathode electrode material) is easily influenced by moisture to be deteriorated and to cause display unevenness. One technology developed to provide an encapsulation structure that protects the OLED against moisture while not spoiling the flexibility of the OLED display device is a thin film encapsulation (TFE) technology. According to the thin film encapsulation technology, an inorganic barrier layer and an organic barrier layer are stacked alternately to allow such thin films to provide a sufficiently high level of water vapor barrier property. From the point of view of the moisture-resistance reliability of the OLED display device, such a thin film encapsulation structure is typically required to have a WVTR (Water Vapor Transmission Rate) lower than, or equal to, 1×10⁻⁴ g/m²/day.

A TFE structure used in OLED display devices commercially available currently includes an organic barrier layer (polymer barrier layer) having a thickness of about 5 μm to about 20 μm. Such a relatively thick organic barrier layer also has a role of flattening a surface of the element substrate. Such a relatively thick organic barrier layer is formed by use of, for example, ink-jetting.

In the meantime, a TFE structure including a relatively thin organic barrier layer has recently been studied. Such a relatively thin organic barrier layer includes an organic resin film (may be referred to as a “solid portion” of the organic barrier layer) provided discretely only in the vicinity of a protruding portion of an inorganic barrier layer (first inorganic barrier layer) provided as an underlying layer for the organic barrier layer (first inorganic barrier layer covering the protruding portion).

For example, Patent Documents Nos. 1 and 2 each describe the following method. An organic material (e.g., acrylic monomer) heated and gasified to be mist-like is supplied onto an element substrate maintained at a temperature lower than, or equal to, room temperature. The organic material is condensed and put into liquid drops on the substrate. The organic material in the liquid drops moves on the substrate by a capillary action or a surface tension to be present locally, more specifically, at a border between a side surface of the protruding portion of the first inorganic barrier layer and a surface of the substrate. Then, the organic material is cured to form the organic resin film at the border. Patent Document No. 3 discloses a method by which the organic resin film is formed also on a flat portion of the element substrate and then is ashed to form an organic barrier layer including a plurality of solid portions discretely distributed. The disclosures of Patent Documents Nos. 1 through 3 are entirely incorporated herein by reference.

### CITATION LIST

### Patent Literature

Patent Document No. 1: WO2014/196137
Patent Document No. 2: Japanese Laid-Open Patent Publication No. 2016-39120
Patent Document No. 3: WO2018/003129

### SUMMARY OF INVENTION

### Technical Problem

According to the studies performed by the present inventor, there is a problem that in the case where the TFE structure is provided, the light utilization efficiency of the organic EL display device is decreased. One reason for this is that light emitted from the OLED (light emitting layer) is reflected by an interface in the TFE structure.

The present invention made to solve the above-described problem has an object of providing an OLED display device suppressing light reflection in a TFE structure, and a method for producing the same.

### Solution to Problem

An organic EL display device according to an embodiment of the present invention is an organic EL display device including a plurality of pixels. The organic EL display device includes an element substrate including a substrate and a plurality of organic EL elements supported by the substrate, and a thin film encapsulation structure covering the plurality of organic EL elements. The thin film encapsulation structure includes a first inorganic barrier layer, an organic barrier layer formed on the first inorganic barrier layer, and a second inorganic barrier layer formed on the organic barrier layer. A surface, of the first inorganic barrier layer, that is in contact with the organic barrier layer includes a plurality of microscopic protrusions, and has a maximum height Rz of roughness of 20 nm or greater and less than 100 nm. It is preferred that the organic barrier layer is formed of a colorless and transparent photocurable resin (e.g., acrylic resin).

In an embodiment, a resin material forming the organic barrier layer fills gaps between the plurality of microscopic protrusions.

In an embodiment, the element substrate further includes a bank layer defining each of the plurality of pixels. The organic barrier layer covers the bank layer and has a flat surface. The organic barrier layer has a thickness of, for example, 3 m or greater and 20 μm or less.

In an embodiment, the organic barrier layer has a thickness of 3 μm or greater and 5 μm or less.

In an embodiment, the element substrate further includes a bank layer defining each of the plurality of pixels. The bank layer has an inclining surface enclosing each of the plurality of pixels. The organic barrier layer includes a plurality of solid portions discretely distributed. The plurality of solid portions include a pixel periphery solid portion extending from a portion, of the first inorganic barrier layer, that is on the inclining surface to an inner peripheral portion of each of the pixels. A surface, of the first inorganic barrier layer, that is in contact with the pixel periphery solid portion has a maximum height Rz of roughness of 20 nm or greater and less than 100 nm.

In an embodiment, the organic barrier layer has a thickness that is 50 nm or greater and less than 200 nm and is greater than the maximum height Rz of roughness of the surface of the first inorganic barrier layer. It is preferred that the organic barrier layer has a thickness that is at least twice, and less than five times, the maximum height Rz.

In an embodiment, the first inorganic barrier layer includes an SiN layer or an SiON layer.

In an embodiment, the first inorganic barrier layer is formed of only an SiN layer and/or an SiON layer.

In an embodiment, the first inorganic barrier layer includes an SiON layer having a refractive index of 1.70 or higher and 1.90 or lower.

In an embodiment, the first inorganic barrier layer further includes an SiO₂ layer.

In an embodiment, the SiO₂ layer has a surface in contact with the organic barrier layer.

In an embodiment, the SiO_{z} layer has a thickness of 20 nm or greater and 50 nm or less.

In an embodiment, the first inorganic barrier layer has a thickness that is 200 nm or greater and 1500 nm or less and is at least five times the maximum height of surface roughness thereof.

A method for producing an organic EL display device according to an embodiment of the present invention is a method for producing any of the above-described organic EL display devices. The method includes a step of forming the first inorganic barrier layer, which includes a step of depositing an inorganic insulating film containing SiN or SiON by use of plasma CVD. The step of depositing the inorganic insulating film includes a step of increasing a temperature of the element substrate or increasing a plasma energy.

A method for producing an organic EL display device according to an embodiment of the present invention is a method for producing any of the above-described organic EL display devices. The method includes a step of forming the first inorganic barrier layer, which includes a step of depositing an inorganic insulating film containing SiN or SiON, and a step of, after the step of depositing the inorganic insulating film, ashing a surface of the inorganic insulating film with a gas containing oxygen or ozone.

### Advantageous Effects of Invention

One embodiment of the present invention provides an organic EL display device suppressing light reflection in a TFE structure, and a method for producing the same.

### BRIEF DESCRIPTION OF DRAWINGS

FIG. 1(a) is a schematic partial cross-sectional view of an active region of an OLED display device 100 according to an embodiment of the present invention, and FIG. 1(b) is a partial cross-sectional view of a TFE structure 10 formed on an OLED 3.

FIG. 2 is a plan view schematically showing a structure of the OLED display device 100 according to an embodiment of the present invention.

FIG. 3(a) through FIG. 3(c) are each a schematic cross-sectional view of an OLED display device 100A including a TFE structure 10A including a relatively thick organic barrier layer 14A; FIG. 3(a) is a cross-sectional view, taken along line 3A-3A′ in FIG. 2, of a portion including a pixel Pix, FIG. 3(b) is a cross-sectional view, taken along line 3A-3A′ in FIG. 2, of a portion including a particle P, and FIG. 3(c) is a cross-sectional view taken along line 3C-3C′ in FIG. 2.

FIG. 4(a) through FIG. 4(c) are each a schematic cross-sectional view of an OLED display device 100B including a TFE structure 10B including a relatively thin organic barrier layer 14B; FIG. 4(a) is a cross-sectional view, taken along line 3A-3A′ in FIG. 2, of a portion including the pixel Pix, FIG. 4(b) is a cross-sectional view, taken along line 3A-3A′ in FIG. 2, of a portion including the particle P, and FIG. 4(c) is a cross-sectional view taken along line 3C-3C′ in FIG. 2.

FIG. 5(a) and FIG. 5(b) are each a schematic cross-sectional view showing a state of an interface between a first inorganic barrier layer 12 and an organic barrier layer 14A in the TFE structure 10A.

FIG. 6 is a schematic cross-sectional view showing a state of an interface between the first inorganic barrier layer 12 and an organic barrier layer 14B in the TFE structure 10B.

### DESCRIPTION OF EMBODIMENTS

Hereinafter, an OLED display device and a method for producing the same according to embodiments of the present invention will be described with reference to the drawings. The embodiments of the present invention are rot limited to the embodiments that are described below as examples. For example, an organic EL display device according to an embodiment of the present invention may include, for example, a glass substrate instead of a flexible substrate.

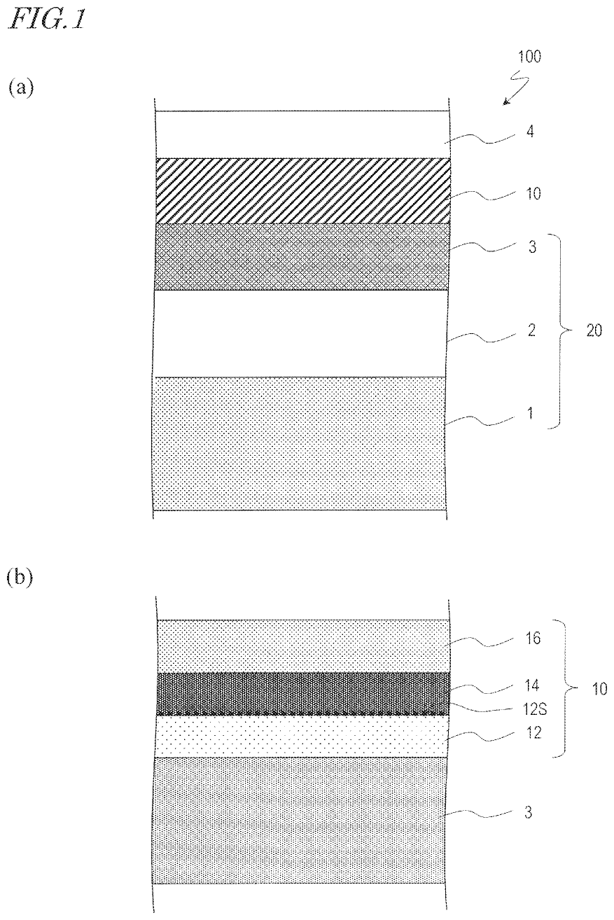

First, with reference to FIG. 1(a) and FIG. 1(b), a basic structure of an OLED display device 100 according to an embodiment of the present invention will be described. FIG. 1(a) is a schematic partial cross-sectional view of an active region of the OLED display device 100 according to an embodiment of the present invention. FIG. 1(b) is a partial cross-sectional view of a TFE structure 10 formed on an OLED 3.

The OLED display device 100 includes a plurality of pixels, and each of the pixels includes at least one organic EL element (OLED). Herein, a structure corresponding to one OLED will be described for the sake of simplicity.

As shown in FIG. 1(a), the OLED display device 100 includes a flexible substrate (hereinafter, may be referred to simply as a “substrate”) 1, a circuit (backplane) 2 formed on the substrate 1 and including a TFT, the OLED 3 formed on the circuit 2, and the TFE structure 10 formed on the OLED 3. The OLED 3 is, for example, of a top emission type. An uppermost portion of the OLED 3 is, for example, an upper electrode or a cap layer (refractive index adjusting layer). An optional polarizing plate 4 is located on the TFE structure 10.

The substrate 1 is, for example, a polyimide film having a thickness of 15 μm. The circuit 2 including the TFT has a thickness of, for example, 4 μm. The OLED 3 has a thickness of, for example, 1 μm. The TFE structure 10 has a thickness of, for example, less than, or equal to, 1.5 μm.

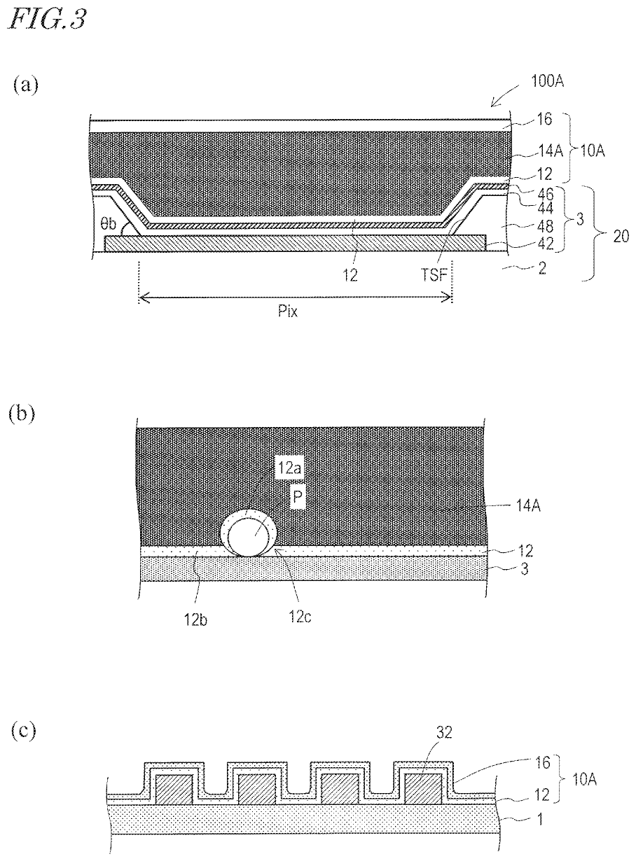

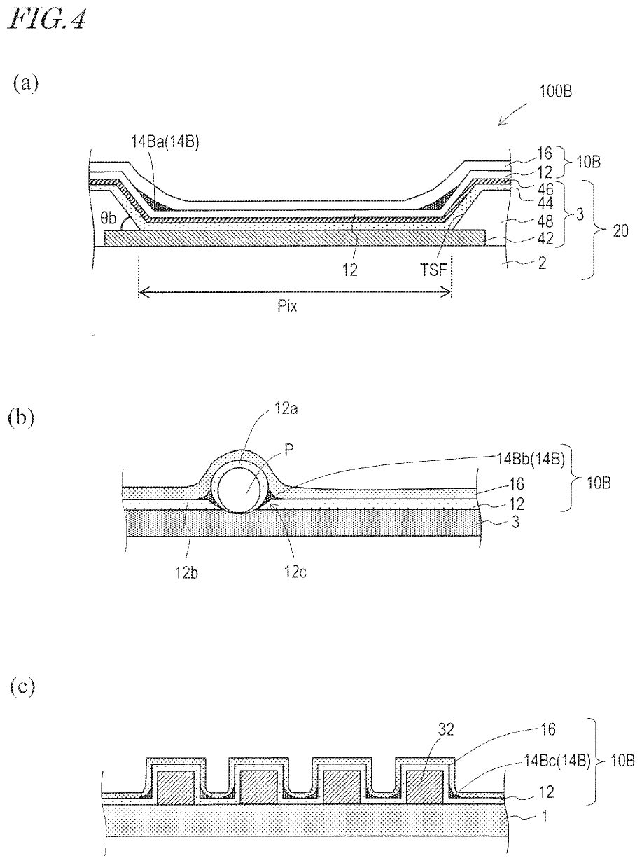

FIG. 1(b) is a partial cross-sectional view of the TFE structure 10 formed on the OLED 3. The TFE structure 10 includes a first inorganic barrier layer (e.g., SiN layer) 12, an organic barrier layer (e.g., acrylic resin layer) 14 formed on the first inorganic barrier layer 12, and a second inorganic barrier layer (e.g., SiN layer) 16 formed on the organic barrier layer 14. The first inorganic barrier layer 12 is formed immediately on the OLED 3. The organic barrier layer 14 may be relatively thick and also act as a flattening layer (see FIG. 3(a)), or may be relatively thin and include a plurality of solid portions discretely distributed (see FIG. 4(a)). It is preferred that the organic barrier layer 14 is formed of a colorless and transparent photocurable resin (e.g., acrylic resin) and, for example, has a visible light transmittance of 95% or higher when having a thickness of 1 μm. The photocurable resin has a refractive index of, for example, about 1.48 to about 1.61.

Among light emitted from the OLED 3, light transmitted through the TFE structure 10 (part of the light emitted from the OLED 3) is output from the OLED display device 100 and used for display. By contrast, a part of the light incident on the TFE structure 10 is reflected by an interface between the first inorganic barrier layer 12 and the organic barrier layer 14. For example, the SiN layer has a refractive index of 1.85, and the acrylic resin layer has a refractive index of 1.54. The refractive index difference (Δn) is as large as 0.31 or greater. Therefore, the light emitted from the OLED 3 is reflected by the interface between the first inorganic barrier layer 12 and the organic barrier layer 14 and is lost.

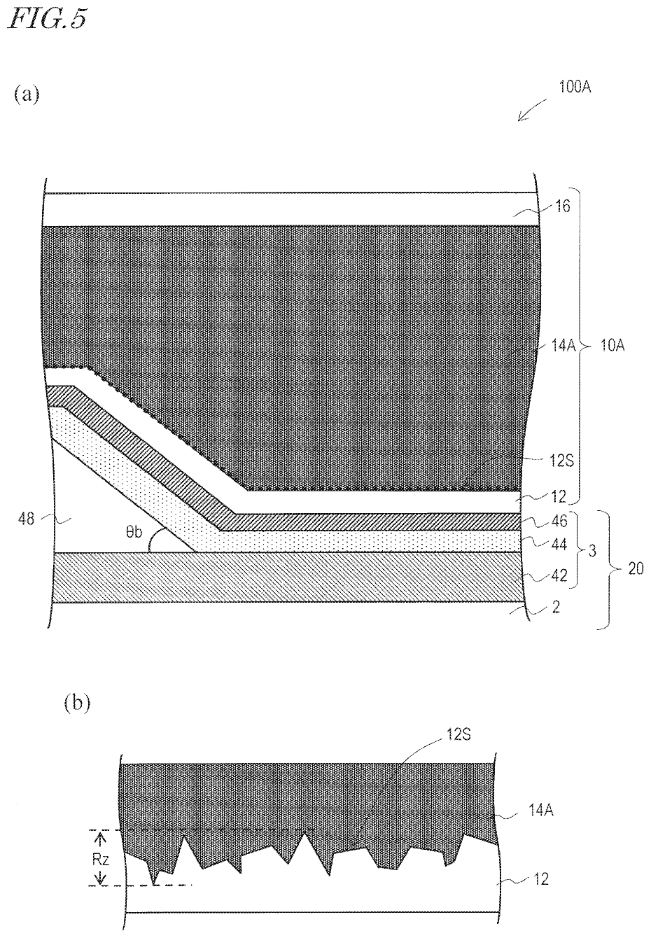

In the TFE structure 10 included in the OLED display device 100 according to an embodiment of the present invention, a surface 12S, of the first inorganic barrier layer 12, that is in contact with the organic barrier layer 14 includes a plurality of microscopic protrusions and has a maximum height Rz of roughness of 20 nm or greater and less than 100 nm (see FIG. 5(b)). With such microscopic protrusions, the effective refractive index of the surface 12S to the visible light continuously changes as described below. Therefore, no interface is present for the visible light, and the surface 12S may suppress the reflection. As a result, the OLED display device 100 according to an embodiment of the present invention may realize a light utilization efficiency higher than that of the conventional OLED display devices.

In this structure, it is preferred that the resin material used to form the organic barrier layer fills gaps between the plurality of microscopic protrusions. A reason for this is that if there is air between the organic barrier layer and the plurality of microscopic protrusions and recesses, the reflection may not be sufficiently suppressed.

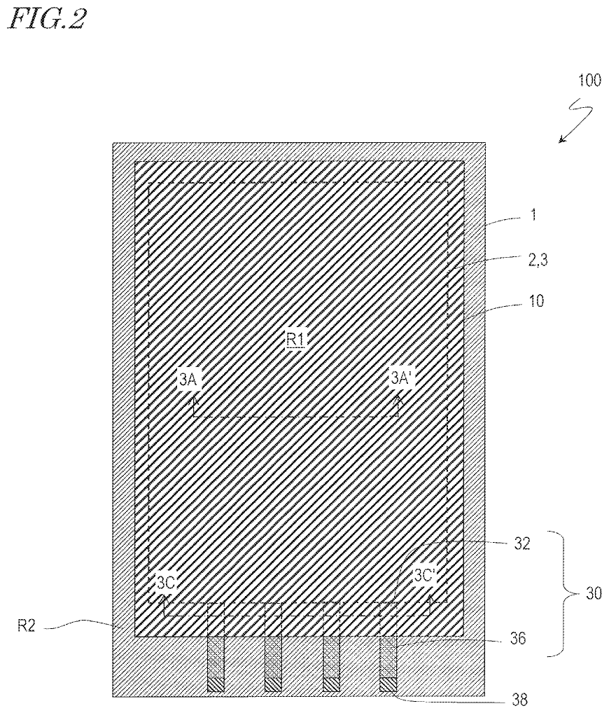

Now, with reference to FIG. 2 through FIG. 4, examples of TFE structure included in the OLED display device according to an embodiment of the present invention will be described.

FIG. 2 is a schematic plan view of the OLED display device 100 according to an embodiment of the present invention.

The OLED display device 100 includes the flexible substrate 1, the circuit (backplane) 2 formed on the flexible substrate 1, a plurality of the OLEDs 3 formed on the circuit 2, and the TFE structure 10 formed on the OLEDs 3. A layer including the plurality of OLEDs 3 may be referred to as an “OLED layer 3”. The circuit 2 and the OLED layer 3 may share a part of components. The optional polarizing plate (see reference sign 4 in FIG. 1) may further be located on the TFE structure 10. In addition, for example, a layer having a touch panel function may be located between the TFE structure 10 and the polarizing plate. Namely, the OLED display device 100 may be altered to a display device including an on-cell type touch panel.

The circuit 2 includes a plurality of TFTs (not shown), and a plurality of gate bus lines (not shown) and a plurality of source bus lines (not shown) each connected to either one of the plurality of TFTs (not shown). The circuit 2 may be a known circuit that drives the plurality of OLEDs 3. The plurality of OLEDs 3 are each connected with either one of the plurality of TFTs included in the circuit 2. The OLEDs 3 may be known OLEDs.

The OLED display device 100 further includes a plurality of terminals 38 located in a peripheral region R2 outer to the active region (region enclosed by the dashed line in FIG. 2) R1, where the plurality of OLEDs 3 are located, and also includes a plurality of lead wires 30 each connecting either one of the plurality of terminals 38 and either one of the plurality of gate bus lines or either one of the plurality of source bus lines to each other. The TFE structure 10 is formed on the plurality of OLEDs 3 and on portions of the plurality of lead wires 30, the portions being closer to the active region R1. Namely, the TFE structure 10 covers the entirety of the active region R1 and is also selectively formed on the portions of the plurality of lead wires 30 that are closer to the active region R1. Neither portions of the plurality of lead wires 30 that are closer to the terminals 38, nor the terminals 38, are covered with the TFE structure 10.

Hereinafter, an example in which the lead wires 30 and the terminals 38 are integrally formed of the same conductive layer will be described. Alternatively, the lead wires 30 and the terminals 38 may be formed of different conductive layers (encompassing stack structures).

Now, with reference to FIG. 3(a) through FIG. 3(c), a structure of an OLED display device 100A including a TFE structure 10A including a relatively thick organic barrier layer 14A will be described. FIG. 3(a) is a cross-sectional view, taken along line 3A-3A′ in FIG. 2, of a portion including a pixel Pix. FIG. 3(b) is a cross-sectional view, taken along line 3A-3A′ in FIG. 2, of a portion including a particle P. FIG. 3(c) is a cross-sectional view taken along line 3C-3C′ in FIG. 2.

As shown in FIG. 3(a), the thin film encapsulation structure 10A includes the first inorganic barrier layer 12, the organic barrier layer 14A formed on the first inorganic barrier layer 12, and the second inorganic barrier layer 16 formed on the organic barrier layer 14A.

An element substrate 20 of the OLED display device 100A further includes a bank layer 48 defining each of the plurality of pixels Pix. The bank layer 48 is formed of an insulating material, and is provided between a lower electrode 42 and an organic layer (organic EL layer) 44 of the OLED 3. The OLED 3 includes the lower electrode 42, the organic layer 44 formed on the lower electrode 42, and an upper electrode 46 formed on the organic layer 44. The lower electrode 42 and the upper electrode 46 respectively act as, for example, an anode and a cathode. The upper electrode 46 is a common electrode formed for the entirety of the pixels in the active region. The lower electrode (pixel electrode) 42 is formed for each of the pixels. In the structure in which the bank layer 48 is present between the lower electrode 42 and the organic layer 44, no electron holes are implanted from the lower electrode 42 into the organic layer 44. Therefore, the region where the bank layer 48 is present does not act as a pixel Pix. For this reason, the bank layer 48 defines an outer perimeter of each of the pixels Pix. The bank layer 48 may be referred to as a “PDL (Pixel Defining Layer)”.

The bank layer 48 includes an opening corresponding to each of the pixels Pix. A side surface of each of the openings of the bank layer 48 has an inclining surface including a forward tapering side surface portion TSF. The inclining surface of the bank layer 48 encloses the corresponding pixel. The bank layer 48 is formed of, for example, a photosensitive resin (e.g., polyimide or acrylic resin). The bank layer 48 has a thickness of, for example, 1 μm or greater and 2 μm or less. The inclining surface of the bank layer 48 is inclined at an inclination angle θb that is smaller than, or equal to, 60 degrees. If the inclination angle θb of the inclining surface of the bank layer 48 is larger than 60 degrees, a defect may be caused in layers located on the bank layer 48.

The organic barrier layer 14A covers the bank layer 48 and has a flat surface. The organic barrier layer 14A is thicker than the bank layer 48, and has a thickness of, for example, 3 μm or greater and 20 μm or less. The second inorganic barrier layer 16 is formed on the flat surface of the organic barrier layer 14A. The organic barrier layer 14A may have a thickness of 3 μm or greater and 5 μm or less. In order to form the organic barrier layer 14A having a thickness exceeding 5 μm, a material having a relatively high viscosity is needed. Such a highly viscous material may not fill the gaps between the plurality of microscopic protrusions of the first inorganic barrier layer 12. If the resin material does not fill the gaps between the plurality of microscopic protrusions, a sufficient effect of preventing reflection may not be provided. In the case of having a thickness of 3 μm or greater and 5 μm or less, the organic barrier layer 14A may be formed of a resin material having a relatively low viscosity. Such a resin material may sufficiently fill the gaps between the plurality of microscopic protrusions of the first inorganic barrier layer 12. The organic barrier layer 14A having such a thickness may be formed by, for example, ink-jetting or slit-coating.

The first inorganic barrier layer 12 and the second inorganic barrier layer 16 are each, for example, an SiN layer, and are each selectively formed only in a predetermined region by plasma CVD by use of a mask so as to cover the active region R1. The organic barrier layer 14A is formed only in a region enclosed by an inorganic barrier layer joint portion, where the first inorganic barrier layer 12 and the second inorganic barrier layer 16 are in direct contact with each other. Therefore, it does not occur that the organic barrier layer 14A acts as a moisture entrance route to allow moisture to reach the active region R1 of the OLED display device. The organic barrier layer 14A is formed of a colorless and transparent photocurable resin (e.g., acrylic resin or epoxy resin) in a predetermined region by use of, for example, ink-jetting. The acrylic resin has a refractive index of, for example, 1.48 or higher and 1.55 or lower. The epoxy resin has a refractive index of, for example, 1.55 or higher and 1.61 or lower.

As schematically shown in FIG. 3(b), in the case where the particle (having a diameter, for example, longer than, or equal to, 1 μm) P is present in the active region R1, a crack (defect) 12c may be formed in the first inorganic barrier layer 12. This is considered to be caused by impingement of an SiN layer 12a growing from a surface of the particle P and an SiN layer 12b growing from a flat portion of a surface of the OLED 3. In the case where such a crack 12c is present, the level of barrier property of the TFE structure is decreased. A structure in which the first inorganic barrier layer 12 is covered with the organic barrier layer 14A having a sufficient thickness may suppress such a decrease in the level of barrier property of the TFE structure 10A.

Now, with reference to FIG. 3(c), a structure of the TFE structure 10A on the lead wires 30 will be described. FIG. 3(c) is a cross-sectional view taken alone line 3C-3C′ in FIG. 2, and is a cross—sectional view of portions 32, of the lead wires 30, closer to the active region R1.

The organic barrier layer 14A is formed only in the active region R1 (region enclosed by the dashed line in FIG. 2) of the TFE structure 10 in FIG. 2, but is not formed outside the active region R1. Therefore, the first inorganic barrier layer 12 and the second inorganic barrier layer 16 are in direct contact with each other outside the active region R1. Namely, as described above, the organic barrier layer 14A is enclosed by the inorganic barrier layer joint portion, where the first inorganic barrier layer 12 and the second inorganic barrier layer 16 are in direct contact with each other. Therefore, as shown in FIG. 3(c), the portions 32, of the lead wires 30, closer to the active region R1 are covered with the first inorganic barrier layer 12 and the second inorganic barrier layer 16.

Now, with reference to FIG. 4(a) through FIG. 4(c), a structure of an OLED display device 100B including a TFE structure 10B including a relatively thin organic barrier layer 14B will be described. FIG. 4(a) is a cross-sectional view, taken along line 3A-3A′ in FIG. 2, of a portion including the pixel Pix. FIG. 4(b) is a cross-sectional view, taken along line 3A-3A′ in FIG. 2, of a portion including the particle P. FIG. 4(c) is a cross-sectional view taken along line 3C-3C′ in FIG. 2.

The organic barrier layer 14B of the TFE structure 10B shown in FIG. 4(a) includes a plurality of solid portions discretely distributed. The plurality of solid portions include a pixel periphery solid portion 14Ba extending from an inclining surface, of the first inorganic barrier layer 12, that is on the side surface of the opening of the bank layer 48 to an inner peripheral portion of the pixel Pix.

As shown in FIG. 4(b), in the case where the particle P is present, a solid portion 14Bb is formed to fill the crack 12c of the first inorganic barrier layer 12, and furthermore, a surface of the organic barrier layer 14Bb couples a surface of the first inorganic barrier layer 12a on the particle P and a surface of the first inorganic barrier layer 12b on the flat portion of the OLED 3 to each other continuously and smoothly. The organic barrier layer 14B is formed by curing a photocurable resin in a liquid state, and therefore, has a recessed surface formed by a surface tension. In this state, the photocurable resin exhibits a high level of wettability to the first inorganic barrier layer 12. If the level of wettability of the photocurable resin to the first inorganic barrier layer 12 is low, the surface of the organic barrier layer 14B may protrude, instead of being recessed. The organic barrier layer 14B may also be formed as a thin film on the surface of the first inorganic barrier layer 12a on the particle P.

The solid portion 14Bb having the recessed surface couples the surface of the first inorganic barrier layer 12a on the particle P and the surface of the first inorganic barrier layer 12b on the flat portion to each other continuously and smoothly. Therefore, the second inorganic barrier layer 16 formed thereon is a fine film with no defect. As can be seen, even if the particle P is present, the organic barrier layer 14B may keep high the level of barrier property of the TFE structure 10B.

Now, with reference to FIG. 4(c), a structure of the TFE structure 10B on the lead wires 30 will be described. FIG. 4(c) is a cross-sectional view taken along line 3C-3C′ in FIG. 2, and more specifically, is a cross-sectional view of the portions 32 of the lead wires 30, the portions 32 being closer to the active region R1.

As shown in FIG. 4(c), the organic barrier layer 14B includes solid portions 14Bc formed in the vicinity of the protruding portions at the surface of the first inorganic barrier layer 12, the protruding portions reflecting the cross-sectional shape of the portions 32 of the lead wires 30. The presence of the solid portions 14Bc allows the second inorganic barrier layer 16 formed on the stepped portions of the first inorganic barrier layer 12 to be a fine film with no defect.

The organic barrier layer 14B may be formed by, for example, the method described in Patent Document No. 1 or 2 mentioned above. For example, in a chamber, a vapor-like or mist-like organic material (e.g., acrylic monomer) is supplied onto an element substrate maintained at a temperature lower than, or equal to, room temperature and is condensed on the element substrate. The organic material put into a liquid state is located locally, more specifically, at the border between the side surface of the protruding portion of the first inorganic barrier layer 12 and the flat portion by a capillary action or a surface tension of the organic material in the liquid state. Then, the organic material is irradiated with, for example, ultraviolet rays to form the solid portion of the organic barrier layer (e.g., acrylic resin layer) 14B at the above-mentioned border in the vicinity of the protruding portion. The organic barrier layer 14B formed by this method does nor substantially include the solid portion on the flat portion. During the formation, the viscosity of the photocurable resin, and the wettability of the photocurable resin to the inclining surface of the bank layer 48 are controlled such that a liquid film is formed also on the inclining surface of the bank layer 48. The surface of the inclining surface may be modified in the quality. As described in Patent Document No. 3, the thickness of the resin layer to be formed first may be adjusted (e.g., to less than 100 nm), and/or ashing conditions (including time) may be adjusted, to form the organic barrier 14B.

In the case where, for example, the solid portions 14Bc are formed from the terminals 38 toward the lead wires 30, the solid portions 14Bc may act as moisture entrance routes to allow moisture to enter the active region R1 of the OLED display device 100B. In order to prevent this, the inorganic barrier layer joint portion, where the first inorganic barrier layer 12 and the second inorganic barrier layer 16 are in direct contact with each other, is formed in a part of the TFE structure 10B, the part being formed on the lead wires 30. Such an inorganic barrier layer joint portion may be formed by, for example, making the tapering angle of the lead wires 30, for example, 70 degrees or smaller, or by irradiating the photocurable resin with infrared rays or the like before the photocurable resin is cured to gasify the photocurable resin.

The organic barrier layer 14B may be formed by, for example, spraying, spin-coating, slit-coating, screen printing or ink-jetting. The method for forming the organic barrier layer 14B may further include an ashing step. The organic barrier layer may be formed of a photocurable resin and exposed to light through a mask. The organic barrier layer may be exposed to light through a mask to form the pixel periphery solid portion 14Ba and also to form the inorganic barrier layer joint portion, where the first inorganic barrier layer 12 and the second inorganic barrier layer 16 are in direct contact with each other.

Now, with reference to FIG. 5(a) and FIG. 5(b), it will be described that in the TFE structure 10A of the OLED display device 100A, reflection is suppressed at the interface between the first inorganic barrier layer 12 and the organic barrier layer 14A.

The first inorganic barrier layer 12 is formed of an SiN layer (silicon nitride; typically, Si₃N₄) having a refractive index of, for example, 1.80 or higher and 2.00 or lower. As is well known, the refractive index may be controlled to some extent by conditions under which the silicon nitride film is formed. Meanwhile, the organic barrier layer 14 is formed of a photocurable acrylic resin having a refractive index of, for example, 1.54. Therefore, the light emitted from the OLED 3 is reflected at the interface between the first inorganic barrier layer 12 and the organic layer 14, and is lost.

As shown in FIG. 5(b), in the TFE structure 10A, the surface 12S, of the first inorganic barrier layer 12, that is in contact with the organic barrier layer 14A includes a plurality of microscopic protrusions, and the maximum height Rz of roughness of the surface 12S is 20 nm or greater and less than 100 nm. The acrylic resin that forms the organic barrier layer fills the gaps between the plurality of microscopic protrusions. The microscopic protrusions have pierced tips. Therefore, the presence ratio of SiN forming the first inorganic barrier layer 12 decreases, and the presence ratio of the acrylic resin forming the organic barrier layer 14A increases, in the direction normal to the first inorganic barrier layer 12. For this reason, the refractive index continuously changes along the interface between the first inorganic barrier layer 12 and the organic barrier layer 14A. Such an interface region having the continuously changing refractive index has a thickness that is approximately equal to the maximum height Rz (according to the JIS) of the surface roughness, and is less than ¼ of the wavelength of visible light (400 nm to 800 nm). Therefore, no interface is present for the visible light, and thus the reflection is suppressed. If the maximum height Rz of the surface roughness is lower than 20 nm, the effect of continuously changing the refractive index at the interface region may not be sufficiently provided. It is preferred that the first inorganic barrier layer 12 has a thickness that is 200 nm or greater and 1500 nm or less, and is at least five times the maximum height Rz of the surface roughness. If the thickness of the first inorganic barrier layer 12 is less than such a range, a sufficiently high level of barrier property may not be provided. If the thickness of the first inorganic barrier layer 12 exceeds 1500 nm, the level of barrier property is saturated, while the tact time is extended. Thus, the mass productivity is decreased.

The SiN layer having such a surface 12S may be formed by, for example, increasing the temperature of the element substrate 20 or increasing the plasma energy in a step of depositing the SiN film by use of plasma CVD. Such an increase in the temperature of the element substrate 20 or in the plasma energy may decrease the density of the SiN film. A conceivable reason for this is that a cluster of SiN easily migrates at the surface.

Alternatively, after the SiN film is deposited by use of plasma CVD, the surface of the SiN film may be ashed with a gas containing oxygen or ozone. The SiN film contains hydrogen. Therefore, ashing performed with a gas containing oxygen or ozone decreases the density of the SiN film and thus roughens the surface during dehydration. Needless to say, this method may be combined with the above-described method.

The inorganic barrier layer 12 may be formed of an SiON layer (silicon oxide nitride layer) instead of the SiN layer. The SiON layer has an advantage of having a higher deposition speed than that of the SiN layer. Also in the case where the SiON layer is used, the surface may be roughened in a similar manner to that in the case where the SiN layer is used. It is preferred that the SiON layer has a refractive index of 1.70 or higher and 1.90 or lower from the point of view of the barrier property.

On the SiN layer or the SiON layer, an SiO₂ layer having a thickness that is less than 100 nm may be formed. SiO₂ forms a sparse film more easily than SiN or SiON, and the SiO₂ layer may obtain a surface having a maximum height Rz of roughness of 20 nm or higher and less than 100 nm by adjustment on the conditions of deposition performed by use of CVD. The SiO₂ layer may have a thickness of 20 nm or greater and 50 nm or less. In the case where SiO₂ is formed by, for example, CVD to have a thickness of 50 nm or less, it often occurs that lumps of SiO₂ are distributed like islands and a film having a constant thickness is not formed. Even an SiO₂ layer having such a non-uniform thickness may suppress light reflection at the interface thereof with the organic barrier layer 14. The non-uniform thickness of the SiO₂ layer may be evaluated by the maximum height of the lumps (islands) of SiO₂. The provision of the SiO₂ layer may improve the adherence of the first inorganic barrier layer 12 with the organic barrier layer 14. In order to improve the adherence of the first inorganic barrier layer 12 with an underlying layer, an SiO₂ layer may be provided below the SiN layer or the SiON layer. The SiO₂ layer has a refractive index of about 1.46.

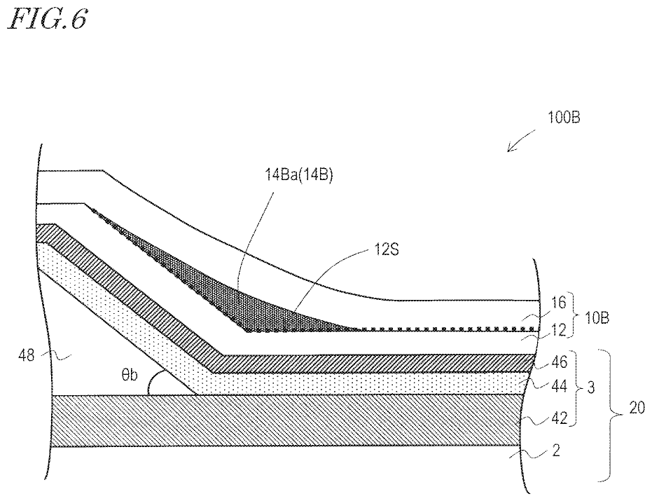

Now, with reference to FIG. 6, it will be described that in the TFE structure 10B of the OLED display device 100B, reflection is suppressed at the interface between the first inorganic barrier layer 12 and the organic barrier layer 14B.

In the TFE structure 10B also, the surface 12S, of the first inorganic barrier layer 12, that is in contact with the pixel periphery solid portion 14Ba of the organic barrier layer 14B includes a plurality of microscopic protrusions, and the maximum height Rz of roughness of the surface 12S is 20 nm or greater and less than 100 nm. The first inorganic barrier layer 12 may be the same as the first inorganic barrier layer 12 in the TFE structure 10A described above.

In the case where in order to form the pixel periphery solid portion 14Ba, an organic resin film is formed also on the flat portion of the element substrate and then is ashed, it is not necessary to remove the entirety of the organic resin present on the flat portion and filling the microscopic gaps (gaps between the microscopic protrusions) of the surface 12S of the first inorganic barrier layer 12. The organic resin may be left filling the microscopic gaps.

It is preferred that the thickness of the organic barrier layer 14B (in this example, the thickness of the pixel periphery solid portion 14Ba) is 50 nm or greater and less than 200 nm and is greater than the maximum height Rz of surface roughness. It is preferred that the thickness of the pixel periphery solid portion 14Ba is at least twice, and less than five times, the maximum height Rz. If such pixel periphery solid portions 14Ba are too thick, the solid portions discretely distributed form a continuous film. The OLED display device 100B, in which the organic barrier layer 14B includes the solid portions discretely distributed, has an advantage of being more flexible than the OLED display device 100A including the relatively thick organic barrier layer 14A.

### INDUSTRIAL APPLICABILITY

An embodiment of the present invention is preferably usable for an OLED display device including a TFE structure, especially, a flexible organic EL display device, and a method for producing the same.

### REFERENCE SIGNS LIST

1 substrate (flexible substrate)
2 circuit
3 OLED layer
4 polarizing plate
10 TFE structure
12 first inorganic barrier layer
12S surface of the first inorganic barrier layer (rough surface)
14 organic barrier layer
14a pixel periphery solid portion
16 second inorganic barrier layer
30 lead wire
38 terminal
42 lower electrode
44 organic layer (organic EL layer)
46 upper electrode
48 bank layer
100, 100A, 100B OLED display device
P particle
Pix pixel
R1 active region
R2 peripheral region

1-15. (canceled)

16. An organic electroluminescent display device including a plurality of pixels, the organic electroluminescent display device comprising:
an element substrate including a substrate and a plurality of organic electroluminescent elements supported by the substrate, and
a thin film encapsulation structure covering the plurality of organic electroluminescent elements,
wherein the thin film encapsulation structure includes a first inorganic barrier layer, an organic barrier layer formed on the first inorganic barrier layer, and a second inorganic barrier layer formed on the organic barrier layer, and
wherein a surface, of the first inorganic barrier layer, that is in contact with the organic barrier layer includes a plurality of microscopic protrusions, and has a maximum height Rz of roughness of 20 nm or greater and less than 100 nm.

17. The organic electroluminescent display device of claim 16, wherein a resin material forming the organic barrier layer fills gaps between the plurality of microscopic protrusions.

18. The organic electroluminescent display device of claim 16,
wherein the element substrate further includes a bank layer defining each of the plurality of pixels, and
wherein the organic barrier layer covers the bank layer and has a flat surface.

19. The organic electroluminescent display device of claim 18, wherein the organic barrier layer has a thickness of 3 μm or greater and 5 μm or less.

20. The organic electroluminescent display device of claim 16,
wherein the element substrate further includes a bank layer defining each of the plurality of pixels,
wherein the bank layer has an inclining surface enclosing each of the plurality of pixels,
wherein the organic barrier layer includes a plurality of solid portions discretely distributed,
wherein the plurality of solid portions include a pixel periphery solid portion extending from a portion, of the first inorganic barrier layer, that is on the inclining surface to an inner peripheral portion of each of the pixels, and
wherein a surface, of the first inorganic barrier layer, that is in contact with the pixel periphery solid portion has a maximum height Rz of roughness of 20 nm or greater and less than 100 nm.

21. The organic electroluminescent display device of claim 20, wherein the organic barrier layer has a thickness that is 50 nm or greater and less than 200 nm and is greater than the maximum height Rz of roughness of the surface of the first inorganic barrier layer.

22. The organic electroluminescent display device of claim 16, wherein the first inorganic barrier layer includes an SiN layer or an SiON layer.

23. The organic electroluminescent display device of claim 22, wherein the first inorganic barrier layer is formed of only an SiN layer and/or an SiON layer.

24. The organic electroluminescent display device of claim 22, wherein the first inorganic barrier layer includes an SiON layer having a refractive index of 1.70 or higher and 1.90 or lower.

25. The organic electroluminescent display device of claim 22, wherein the first inorganic barrier layer further includes an SiO₂ layer.

26. The organic electroluminescent display device of claim 25, wherein the SiO₂ layer has a surface in contact with the organic barrier layer.

27. The organic electroluminescent display device of claim 26, wherein the SiO₂ layer has a thickness of 20 nm or greater and 50 nm or less.

28. The organic electroluminescent display device of claim 16, wherein the first inorganic barrier layer has a thickness that is 200 nm or greater and 1500 nm or less and is at least five times the maximum height of surface roughness thereof.

29. A method for producing the organic electroluminescent display device of claim 16, the method comprising:
a step of forming the first inorganic barrier layer, which includes a step of depositing an inorganic insulating film containing SiN or SiON by use of plasma CVD,
wherein the step of depositing the inorganic insulating film includes a step of increasing a temperature of the element substrate or increasing a plasma energy.

30. A method for producing the organic electroluminescent display device of claim 16, the method comprising:
a step of forming the first inorganic barrier layer, which includes a step of depositing an inorganic insulating film containing SiN or SiON, and a step of, after the step of depositing the inorganic insulating film, ashing a surface of the inorganic insulating film with a gas containing oxygen or ozone.
